(19) United States
(12) Patent Application Publication
(10) Pub. No.: US 2017/0059216 A1
(43) Pub. Date: Mar. 2, 2017

(54) Inductive and Photovoltaic Rechargeable Battery Powered Thermoelectric Cooler System for Consumable Liquids or Food

(71) Applicant: Shaun Douglas Wiggins, Saratoga Springs, NY (US)

(72) Inventor: Shaun Douglas Wiggins, Saratoga Springs, NY (US)

(21) Appl. No.: 14/833,359

(22) Filed: Aug. 24, 2015

(51) Int. Cl. F25B 21/04; H01M 10/46; B65D 81/38; H02J 7/02; H02J 7/35; A47J 41/00; H01L 35/32; H01M 10/42

(52) U.S. Cl. CPC F25B 21/04; H01L 35/32; H01M 10/465; H01M 10/4257; H02J 7/025; H02J 7/35; A47J 41/005; A47J 41/0077; B65D 81/3841; H01M 2010/4271; H01M 2010/4278; H01M 2220/30

(57) ABSTRACT

The premise of the device's operation is employing the Peltier Effect—using thermoelectric coolers—to keep smaller amounts of consumable liquids or food either cold or hot during short distances of travel. The device is a portable metal container with an inner container encompassed by an outer container to provide an insulation moat that aids in maintaining a level interior temperature. The inner container has adhered cascaded thermoelectric coolers—powered by a rechargeable battery (or batteries) using on-board inductive and photovoltaic charging systems—that are equidistance apart. The adhered thermoelectric coolers—depending on the configuration—extract heat from or add heat to the interior of the inner container, resulting in a cooler or hotter temperature respectively. The resulting effect is that consumable liquids or food are made or kept cool or warm.

The device is a metal container encompassed by a slightly larger metal container with a moat of air between the two so as to allow for the interior temperature of the smaller metal container to remain constant longer. The interior metal container has thermoelectric coolers (TECs) interfacing its external metal. The opposite sides of the TECs are exposed to ambient air (so they are not encompassed within the air moat). The TECs are used to add heat to or remove heat from the interior of the smaller metal container, depending on the polarity for the TECs. The device is built to carry consumable foods or beverages and to keep said foods or beverages hot or cold depending on user's preference. The TECs are powered by a rechargeable lithium battery; the lithium battery is recharged using an inductive charging base. Additionally, while in transit, the lithium battery receives a continuous charge from photovoltaic panels. All charging is managed by a microcontroller.

### BRIEF DESCRIPTION OF THE VIEWS OF THE DRAWINGS

FIG. 1 shows a cross section view of the Inductive and Photovoltaic Rechargeable Battery Powered Thermoelectric Cooler System for Consumable Liquids or Food.

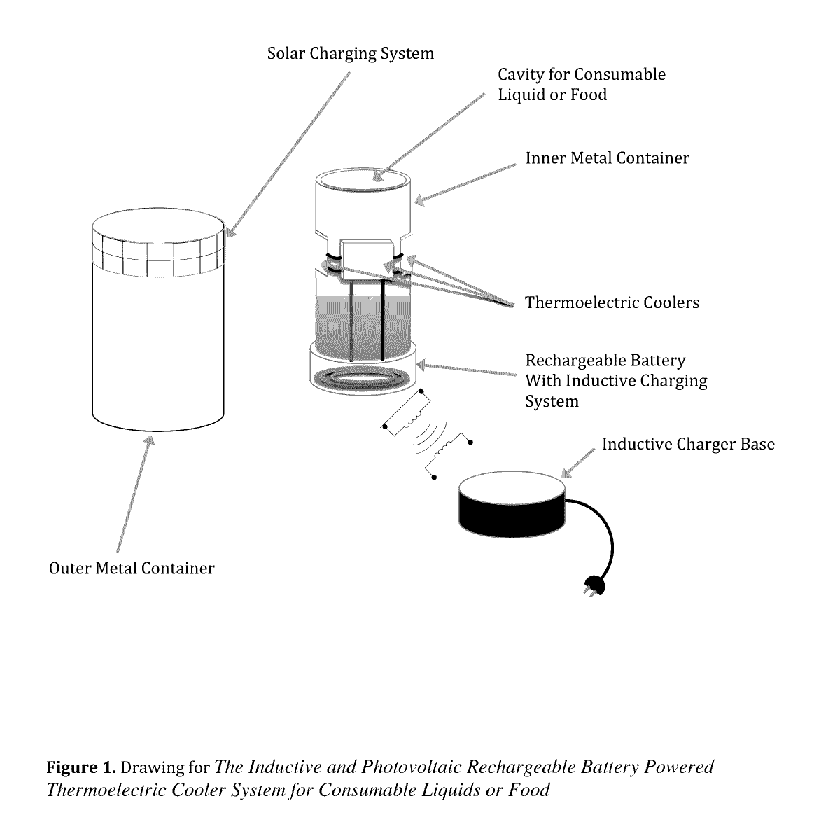

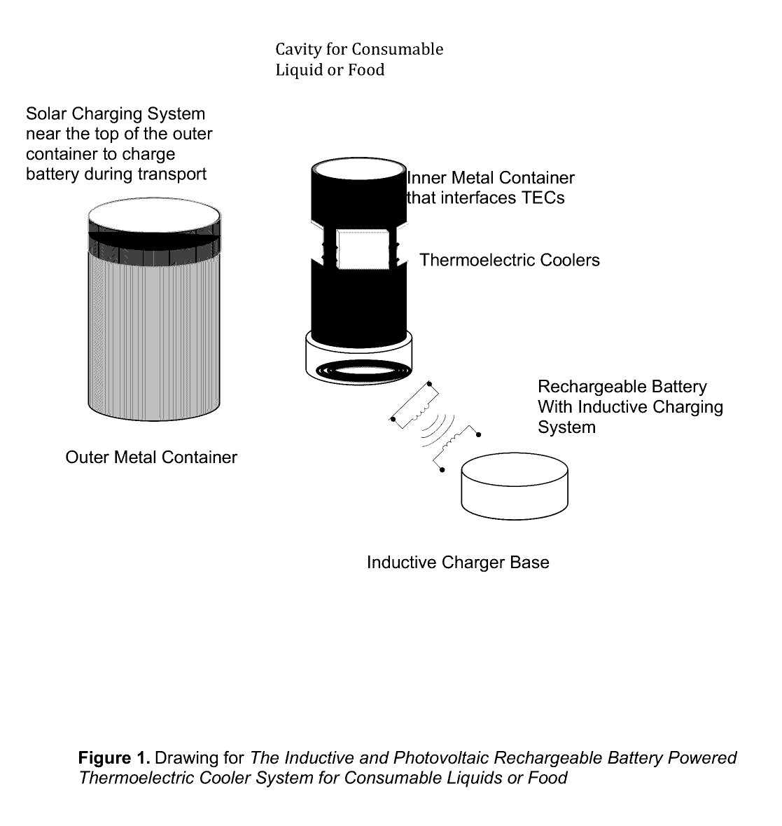

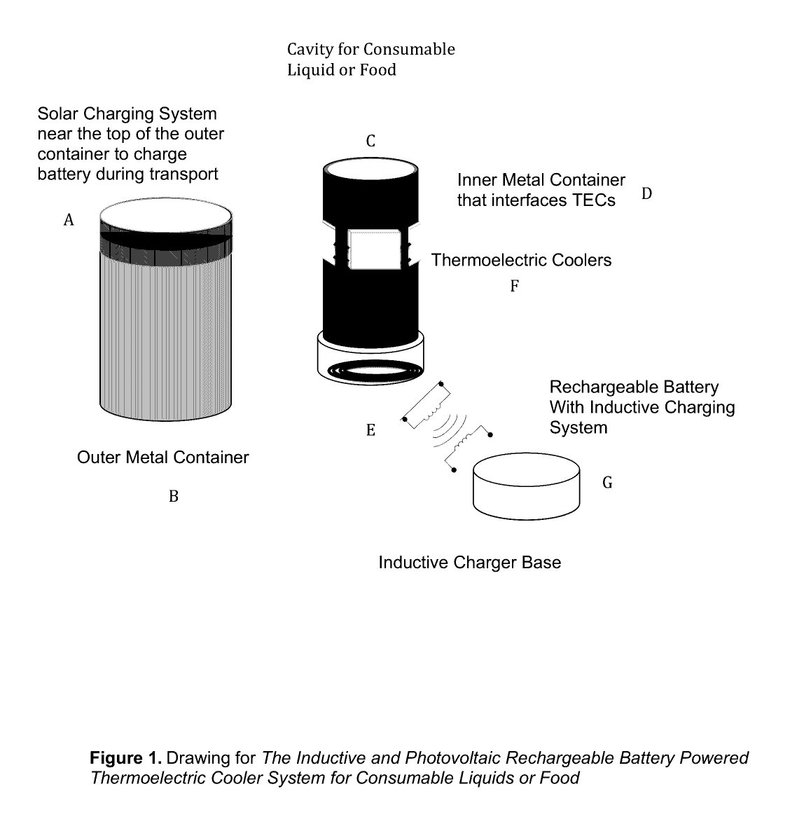

This invention will be manufactured using a metal press to create the inner and outer containers. The TECs will be glued to the inner container with a temperature conducting adhesive. Electronic and battery will be on the bottom to the container and a welding process will hermetically seal the containers together creating the air moat. Finally, flexible photovoltaic panels will be attached to the external container with all wiring properly connected to the TECs for powering. Eventually, the containers will be 3-D printed so as to simplify the manufacturing process.

The invention will be widely manufactured using 3-D printing to more easily produce large quantities in a shorter period of time. With 3-D printing, the photovoltaic panels, the lithium battery and the TECs can easily be settled into pre-printed slots.

### DETAILED DESCRIPTION OF THE INVENTION

“A” shows the solar recharging array that sits around the outside of the “B” the outer metal container. “C” is the inner metal container that actually holds the food or beverage. “F” details the Thermoelectric Coolers that will be used to heat or cool the food or beverage. “E” is the Inductive Charging Unit at the bottom of the container that is used to recharge the battery when housed on the Inductive Charging base “G”.

1. With an inner metal container surrounded by an outer metal container resulting in an insulating moat in-between, the device has multiple equidistant thermoelectric coolers (TECs) adhered to the inner metal container that provide cooling (with the cool side of the TECs) or heating (with the hot side of the TECs) to consumable liquids or food that are within the cavity of the device.

2. The TECs are powered by a rechargeable battery (or batteries) that use an inductive charging system to provide the rechargeable battery (or batteries) with its primary charge through a coil system embedded in the container during periodic base recharge. The device rests on a charging station that uses an electromagnetic field to transfer energy from the charging station to the device that has a coil system that recharges the battery using inductive coupling.

3. During container transport or use, a photovoltaic battery charging system provides a secondary charge to the battery (or batteries) through a portable solar array that is embedded on the outer container. Power from the solar array interfaces a DC-to-DC converter to manage the voltage level.

4. Both the inductive and photovoltaic charging systems are monitored and managed by a microcontroller. The microcontroller helps to ensure that the preset overcharge limit is not exceeded by the induction and photovoltaic charging systems. Additionally, the microcontroller helps the power converter regulate the solar array charging process.

5. The device has a closeable opening to the inner cavity to allow an individual to drink or eat the cool or warm liquid or food.
